(19) United States
(12) Patent Application Publication
(10) Pub. No.: US 2021/0336166 A1
(43) Pub. Date: Oct. 28, 2021

(54) FLEXIBLE DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Songxian WEN, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/619,098

(22) PCT Filed: Aug. 20, 2019
(86) PCT No.: PCT/CN2019/101481

§ 371 Date: Dec. 4, 2019

(30) Foreign Application Priority Data
Aug. 6, 2019 (CN) 201910722801.1

(51) Int. Cl. H01L 51/00; H01L 27/32

(52) U.S. Cl. CPC H01L 51/0097; H01L 27/3258; H01L 27/3279; H01L 27/3262

(57) ABSTRACT

The present invention provides a flexible display panel. The flexible display panel includes a flexible substrate, a TFT layer, a planarization layer, and an OLED layer. An anode layer of the OLED layer has a stress adjustment pattern in a bending region. Unlike conventional techniques which completely etches away an anode layer, the present invention forms the stress adjustment pattern in the anode layer in the bending region to adjust a neutral axis, so that when the flexible display panel is bent, a neutral surface is in a layer where a metal wire is placed or is close to the metal wire. Also, a tensile stress in the bending region is spread evenly through a support function of the stress adjustment pattern, the tensile stress of the metal wire is reduced.

### 1. FIELD OF DISCLOSURE

The present invention relates to a field of display devices and in particular, to a flexible display panel.

### 2. DESCRIPTION OF RELATED ART

Among the flat panel display technologies, organic light-emitting diode (OLED) displays have advantages such as being thin and light, active illumination, fast response time, large viewing angles, wide color gamut, high brightness, low power consumption, and flexible screens. Therefore, industries and scientific research institutes have a great interest in the OLED displays. Recently, a flexible display device that has a display panel on a flexible substrate made of, for example, a plastic flexible material has become a key product among the next-generation display devices.

A narrow border design or even a borderless design of the display device is the mainstream of the current display technology. In terms of flexible display products, the flexible display product is fabricated on a flexible base, so when manufacturing a narrow bezel device, it is required to bend an edge of the device to achieve a narrow bezel design of a bonding region, and a bending radius should be very small. When the bonding region is bent toward a rear side of a display surface, a being region (i.e., a bending area, referred to as BA for short) is formed between the bonding region and the display region, and the bonding region and the display region are connected by a metal wire passing through the bending region for transmitting signals.

As shown in FIGS. 1 and 2, the bending region of the conventional flexible display panel includes a polyimide (PI) flexible substrate 10, an interlayer insulating layer (ILD) 20 disposed on the flexible substrate 10, and a metal wire 30 disposed on the interlayer insulating layer 20 and arranged in a same layer as a source/drain (SD) electrode, a planarization layer (PLN) 40 disposed on the interlayer insulating layer 20 and the metal wire 30, and a pixel defining layer (PDL) 50 disposed on the planarization layer 40. During a bending process, a neutral layer is usually in the flexible substrate 10, and the metal wire 30 distributed in the bending region bears stress and may deform from bending. After bent many times or receiving excessive stress, the metal wire 30 may break or have cracks, thereby affecting signal transmission and leading to poor performance or even display failure of a display screen.

At present, the industry generally applies an ultraviolet (UV) adhesive in the bending region to protect the metal wire. This helps to reduce a tensile stress of the metal wire in the bending region but with a limited effect. The metal wire in the conventional structure still receive high tensile stress.

### SUMMARY

The present invention is directed to a flexible display panel. The flexible display panel forms a stress adjustment pattern in an anode layer in a bending region, so as to adjust a neutral axis and spread stress. Therefore, when the flexible display panel is bent, a neutral surface is in a layer where a metal wire is disposed or is close to the metal wire, and tensile stress of the metal wire is reduced, thereby reducing a risk of breakage of the metal wire and improving bending resistance and product reliability.

Accordingly, the present invention provides a flexible display panel, comprising:

a flexible substrate; and

a thin film transistor (TFT) layer, a planarization layer, and an organic light-emitting diode (OLED) layer sequentially disposed on the flexible substrate from bottom to top;

wherein the TFT layer comprises an interlayer insulating layer disposed on the flexible substrate and a source/drain metal layer disposed on the interlayer insulating layer;

wherein the OLED layer comprises an anode layer disposed on the planarization layer;

wherein the flexible display panel comprises a display region and a bending region arranged at one side of the display region;

wherein the source/drain metal layer comprises a metal wire passing through the bending region; and

wherein the anode layer is provided with a stress adjustment pattern in the bending region.

The stress adjustment pattern is a full planar structure in the bending region.

The stress adjustment pattern is a grid structure.

The stress adjustment pattern comprises a strip shape parallel to the metal wire.

The stress adjustment pattern comprises a strip shape perpendicular to the metal wire.

The interlayer insulating layer is provided with a deep hole in the bending region, and the deep hole is filled with an organic photoresist block.

The OLED layer further comprises a pixel defining layer disposed on the planarization layer and the anode layer, an organic light-emitting layer disposed on the anode layer and surrounded by the pixel defining layer, and a cathode layer disposed on the pixel defining layer and the organic light-emitting layer.

The TFT layer further comprises a gate metal layer and an active layer arranged with the source/drain metal layer in a stacked manner.

The anode layer is provided with an anode electrode spaced apart from the stress adjustment pattern in the display region.

The flexible substrate is a polyimide flexible substrate.

Advantages of the present invention: The flexible display panel comprises the flexible substrate, the TFT layer, the planarization layer, and the OLED layer. The anode layer of the OLED layer has the stress adjustment pattern in the bending region. In prior arts, an anode layer in a bending region is completely etched away. By contrast, the anode layer of the present invention forms the stress adjustment pattern in the bending region, and a neutral axis is adjusted through the stress adjustment pattern. Therefore, when the flexible display panel is bent, a neutral surface is in a layer where the metal wire is disposed or is close to the metal wire. At the same time, the tensile stress in the bending region is spread evenly due to a support function of the stress adjustment pattern, thereby reducing the tensile stress of the metal wire, thus reducing a risk of breakage of the metal wire and improving the bending resistance and product reliability.

### BRIEF DESCRIPTION OF DRAWINGS

Please refer to the following detailed description and accompanying drawings for a better understanding of features and technical contents of the present invention. The accompanying drawings are only provided for illustrative purposes and ease of description and are not intended to limit the present invention.

FIG. 1 is a schematic cross-sectional view illustrating a bending region of a conventional flexible display panel, wherein the cross-sectional view is taken along a bending direction, i.e., an extending direction of a metal wire;

FIG. 2 is a schematic cross-sectional view taken along a direction perpendicular to the extending direction of the metal wire, illustrating the bending region of the conventional flexible display panel of FIG. 1;

FIG. 3 is a schematic structural view illustrating a bending region of a flexible display panel according to the present invention;

FIG. 4 is a schematic structural view illustrating a display region of the flexible display panel according to the present invention; and

FIG. 5 is a top view illustrating a metal wire and a stress adjustment pattern of the flexible display panel according to the present invention.

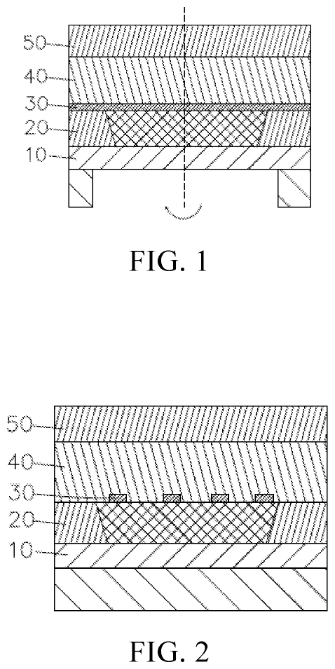

### DETAILED DESCRIPTION OF EMBODIMENTS

In order to describe the technical solutions and functions of the present invention, the following detailed description is provided in conjunction with preferable embodiments of the invention and the accompanying drawings.

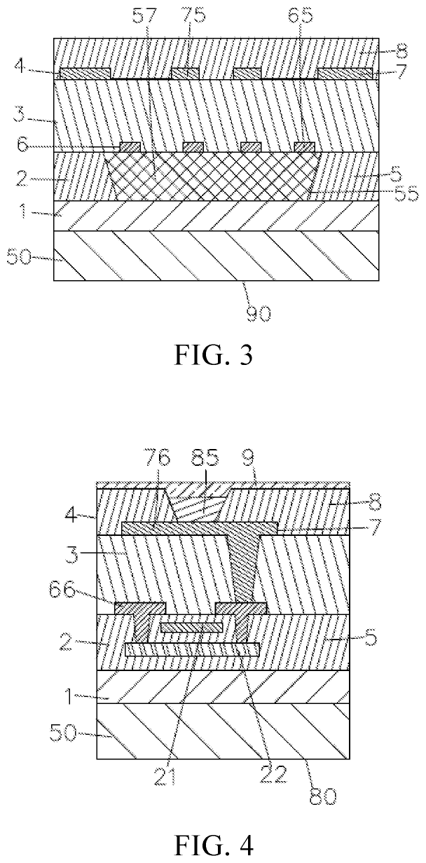

Referring to FIGS. 3 and 4, the present invention provides a flexible display panel. The flexible display panel comprises a flexible substrate 1 and a thin film transistor (TFT) layer 2, a planarization layer 3, and an organic light-emitting diode (OLED) layer 4 sequentially disposed on the flexible substrate 1 from bottom to top.

The TFT layer 2 comprises an interlayer insulating layer 5 disposed on the flexible substrate 1 and a source/drain metal layer 6 disposed on the interlayer insulating layer 5. The TFT layer 2 further comprises a gate metal layer 21 and an active layer 22 arranged with the source/drain metal layer 6 in a stacked manner, wherein the interlayer insulating layer 5 spaces the gate metal layer 21 and the active layer 22 apart from the source/drain metal layer 6.

The OLED layer 4 comprises an anode layer 7 disposed on the planarization layer 3. The OLED layer 4 further comprises a pixel defining layer 8 disposed on the planarization layer 3 and the anode layer 7, an organic light-emitting layer 85 disposed on the anode layer 7 and surrounded by the pixel defining layer 8, and a cathode layer 9 disposed on the pixel defining layer 8 and the organic light-emitting layer 85.

The flexible display panel comprises a display region 80, a bonding region outside the display region 80, and a bending region 90 arranged between the display region 80 and the bonding region.

Specifically, a support plate 50 is disposed on a back surface of the flexible substrate 1 to support and protect the flexible substrate 10. The support plate 50 is made of polyethylene terephthalate (PET). The support plate 50 is provided with a groove corresponding to the bending region 90 to facilitate bending of the flexible display panel in the bending region 90.

The source/drain metal layer 6 comprises a source/drain electrode 66 in the display region 80 and also comprises a metal wire 65 passing through the bending region 90.

The anode layer 7 comprises an anode electrode 76 in the display region 80, and the anode layer 7 is provided with a stress adjustment pattern 75 in the bending region 90, wherein the stress adjustment pattern 75 is spaced apart from the anode electrode 76. The stress adjustment pattern 75 functions to adjust a neutral axis and support, so that when the flexible display panel is bent, a neutral surface is in a layer where the metal wire is disposed or is close to the metal wire, thereby reducing a tensile stress of the metal wire, thus reducing a risk of breakage of the metal wire and improving bending resistance and product reliability.

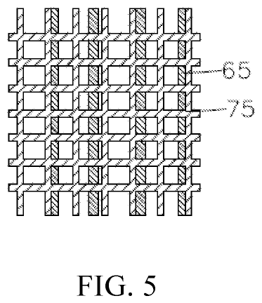

The stress adjustment pattern 75 is a full planar structure in the bending region 90, or is a grid structure as shown in FIG. 5. Alternatively, the stress adjustment pattern 75 has a strip shape parallel to the metal wire 65.

Specifically, in a manufacturing process, after the anode layer 7 is completely deposited, the anode layer 7 in the bending region 90 is etched into the stress adjustment pattern 75 by exposure and development steps.

The interlayer insulating layer 5 is provided with a deep hole 55 in the bending region 90. The deep hole 55 is filled with an organic photoresist block 57, thereby buffering stress and further reducing the risk of breakage of the metal wire.

The flexible substrate 1 is a polyimide flexible substrate. In the flexible display panel of the present invention, by means of the stress adjustment pattern 75 of the anode layer 7 in the bending region 90, the neutral axis is adjusted. Therefore, when the flexible display panel is bent, the neutral surface is in the layer where the metal wire 65 is disposed or is close to the metal wire 65. Also, the tensile stress in the bending region 90 is distributed evenly through a support function of the stress adjustment pattern 75, thereby reducing the tensile stress of the metal wire 65, thus reducing the risk of breakage of the metal wire 65 and improving bending resistance and product reliability.

In summary, the flexible display panel comprises the flexible substrate, the TFT layer, the planarization layer, and the OLED layer. The anode layer of the OLED layer has the stress adjustment pattern in the bending region. In prior arts, an anode layer is completely etched away. By contrast, the anode layer of the present invention forms the stress adjustment pattern in the bending region, and the neutral axis is adjusted through the stress adjustment pattern. Therefore, when the flexible display panel is bent, the neutral surface is in the layer where the metal wire is disposed or is close to the metal wire. At the same time, the tensile stress in the bending region is spread evenly due to the support function of the stress adjustment pattern, thereby reducing the tensile stress of the metal wire, thus reducing the risk of breakage of the metal wire and improving the bending resistance and product reliability.

It should be noted that, various changes and modifications can be made by persons of ordinary skills in the art in accordance with the technical solutions and technical concept of the present invention, and all such changes and modifications should be deemed to be within the protection scope of the present invention defined by the appended claims.

What is claimed is:

1. A flexible display panel, comprising:
a flexible substrate; and
a thin film transistor (TFT) layer, a planarization layer, and an organic light-emitting diode (OLED) layer sequentially disposed on the flexible substrate from bottom to top;
wherein the TFT layer comprises an interlayer insulating layer disposed on the flexible substrate and a source/drain metal layer disposed on the interlayer insulating layer;
wherein the OLED layer comprises an anode layer disposed on the planarization layer;
wherein the flexible display panel comprises a display region and a bending region arranged at one side of the display region;
wherein the source/drain metal layer comprises a metal wire passing through the bending region; and
wherein the anode layer is provided with a stress adjustment pattern in the bending region.

2. The flexible display panel according to claim 1, wherein the stress adjustment pattern is a full planar structure in the bending region.

3. The flexible display panel according to claim 1, wherein the stress adjustment pattern is a grid structure.

4. The flexible display panel according to claim 1, wherein the stress adjustment pattern comprises a strip shape parallel to the metal wire.

5. The flexible display panel according to claim 1, wherein the stress adjustment pattern comprises a strip shape perpendicular to the metal wire.

6. The flexible display panel according to claim 1, wherein the interlayer insulating layer is provided with a deep hole in the bending region, and the deep hole is filled with an organic photoresist block.

7. The flexible display panel according to claim 1, wherein the OLED layer further comprises a pixel defining layer disposed on the planarization layer and the anode layer, an organic light-emitting layer disposed on the anode layer and surrounded by the pixel defining layer, and a cathode layer disposed on the pixel defining layer and the organic light-emitting layer.

8. The flexible display panel according to claim 1, wherein the TFT layer further comprises a gate metal layer and an active layer arranged with the source/drain metal layer in a stacked manner.

9. The flexible display panel according to claim 1, wherein the anode layer is provided with an anode electrode spaced apart from the stress adjustment pattern in the display region.

10. The flexible display panel according to claim 1, wherein the flexible substrate is a polyimide flexible substrate.
